(19) United States
(12) Patent Application Publication
(10) Pub. No.: US 2004/0241996 A1
(43) Pub. Date: Dec. 2, 2004

(54) Apparatus and method for preventing substrates from being contaminated by condensed liquid

(75) Inventors: Chien-Hsiung Hung, Tainan City (TW); Ming-Tang Chiang, Siluo Township (TW); Ming-Yi Huang, Douliou City (TW); Ming-Yuan Tsai, Taiping City (TW); Shun-Huang Peng, Hsinchu City (TW)

Correspondence Address: BACON & THOMAS, PLLC, 625 SLATERS LANE, FOURTH FLOOR, ALEXANDRIA, VA, 22314

(73) Assignee: AU Optronics Corp., Hsinchu City (TW)

(21) Appl. No.: 10/841,641

(22) Filed: May 10, 2004

(30) Foreign Application Priority Data
May 28, 2003 (TW) 092114431

(51) Int. Cl. H01L 21/302; H01L 21/461

(52) U.S. Cl. 438/689

(57) ABSTRACT

An apparatus for preventing a substrate from being contaminated by condensed liquid is disclosed to be adapted to a substrate, comprising a reaction chamber having at least a doorway on one side for the substrate to enter or exit wherein the chamber receives the substrate and a process fluid to proceed with a processing step, a conveyor unit for delivering the substrate into or out of the reaction chamber via the doorway, a first jet device disposed on the delivery route of the conveyor unit external to the reaction chamber to eject a gas out in a direction toward the substrate on the conveyor unit, and a second jet device disposed on one side of the doorway external to the reaction chamber to eject a gas out in a direction toward the doorway. Also, a method for preventing a substrate from being contaminated by condensed liquid is provided.

### BACKGROUND OF THE INVENTION

1. Field of the Invention

The present invention relates to a method for preventing a substrate becoming contaminated by condensed liquid, and more particularly to a method for preventing a substrate becoming contaminated by condensed liquid during a photoresist stripping process.

2. Description of Related Art

A lithography process is deemed as one of the most important steps for fabricating a semiconductor or a flat panel display. All patterns or impurity regions relating to the structure of a component are subject to the lithograph process. The technology of lithography process is very complex. First, a photoresist layer is primarily formed over a wafer surface. Then, the photoresist layer is selectively exposed by parallel beams in accordance with a mask having a predetermined pattern. Then, the masked pattern is transferred to the photoresist layer by a development. Subsequent processing steps such as etching and an ion implantation are performed. After completion of these processing steps, the photoresist is no longer useful and has to be stripped from the wafer surface. This final processing step is generally called a photoresist stripping.

FIG. 1 shows the current process for stripping a photoresist. A substrate 10 is subject to the photoresist stripping process in a stripper chamber 20, and then enters a rinsing chamber 30 for removing the photoresist stripper from the substrate. It is found from the production line that water spots are generated on the surface of substrate 10 when passing through a separation plate 40 between the stripper chamber 20 and the rinsing chamber 30. The water spots result from the ambient photoresist stripper vapor and water vapor condensed by cool air flowing from the rinsing chamber 30 to the stripper chamber 20 having a warmer temperature (about 65 to 70° C.). The water spots are generated on the separation plate 40 that is automatically opened when the substrate enters the rinsing chamber 30. The phenomenon of the vapor condensation is more obvious when a gas knife 50 in the rinsing chamber 30 is regulated to a direction toward the separation plate 40. A mixture of deionized water and the photoresist stripper is condensed on the inner sidewall of the separation plate 40, and then, the condensed liquid droplets impinge on the substrate 10. Further, the gas knife 50 in the rinsing chamber 30 sweeps the substrate 10 off, causing formation of water spots. As a result, production yield and reliability is degraded.

Therefore, it is desirable to provide an improved apparatus and method for preventing substrate from being contaminated by condensed liquid to mitigate and/or obviate the aforementioned problems.

### SUMMARY OF THE INVENTION

Accordingly, it is an object of the present invention to provide an apparatus for preventing a substrate from being contaminated by condensed liquid so as to avoid formation of water spots on the substrate surface and to increase panel yield and component reliability. Another object of the present invention is to provide a method for preventing a substrate from being contaminated by condensed liquid so as to avoid formation of water spots on the substrate surface and to increase panel yield and component reliability.

To attain the foregoing objects, an app-aratus for preventing a substrate from being contaminated by condensed liquid according to the present invention is adapted to a substrate, comprising a reaction chamber having at least a doorway on one side for the substrate to enter or exit wherein the chamber receives the substrate and a process fluid to proceed with a processing step, a conveyor unit for delivering the substrate into or out of the reaction chamber via the doorway, a first jet device disposed on the delivery route of the conveyor unit external to the reaction chamber to eject a gas in a direction toward the substrate on the conveyor unit, and a second jet device disposed on one side of the doorway external to the reaction chamber to eject a gas in a direction toward the doorway.

To attain the foregoing objects, a method for preventing a substrate from being contaminated by condensed liquid according to the present invention is adapted to a substrate, comprising the following steps: providing a reaction chamber having at least a doorway on one side for the substrate to enter or exit wherein the chamber receives the substrate and a process fluid to proceed with a processing step, a conveyor unit for delivering the substrate into or out of the reaction chamber via the doorway, a first jet device disposed on the delivery route of the conveyor unit external to the reaction chamber, and a second jet device disposed on one side of the doorway external to the reaction chamber; and ejecting a gas from the second jet device in a direction toward the doorway.

The substrate adapted to an apparatus and method for preventing a substrate from being contaminated by condensed liquid according to the present invention is not specifically defined. Preferably, the substrate is a glass substrate or a silicon wafer. The conveyor unit in an apparatus and method for preventing a substrate from being contaminated by condensed liquid according to the present invention is not specifically defined. Preferably, the conveyor unit is a roller or a conveyor belt. It is preferable for the processing step applied to an apparatus and method for preventing a substrate from being contaminated by condensed liquid according to the present invention is a photoresist stripping or an etching step, and more preferably, a wet photoresist stripping or a wet etching step. The process fluid used in an apparatus and method for preventing a substrate from being contaminated by condensed liquid according to the present invention is not specifically defined. The fluid can be of any suitable type to be used in association with the processing step. Preferably, the fluid is a photoresist stripper or an acid solution. The first or second jet device in an apparatus and method for preventing a substrate from being contaminated by condensed liquid according to the present invention preferably is a nozzle, a gas knife or a wind knife. The doorway in an apparatus and method for preventing a substrate from being contaminated by condensed liquid according to the present invention preferably is a valve. In a method for preventing a substrate from being contaminated by condensed liquid according to the present invention, the state (either open or closed) of the doorway is not specifically defined when a gas is ejected from the second jet device in a direction toward the doorway. The first jet device ejecting a gas in a direction toward the substrate on the conveyor unit can be made on, before or after a gas is ejected from the second jet device in a direction toward the doorway.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of a conventional stripper machine.

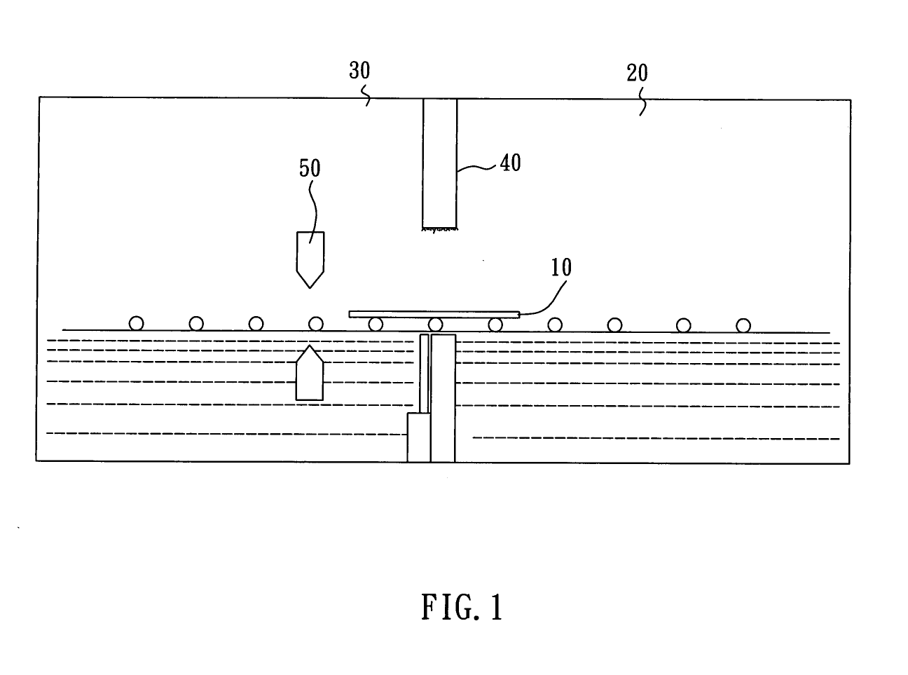

FIG. 2 is a cross-sectional view of a stripper machine according to a preferred embodiment of the present invention.

### DETAILED DESCRIPTION OF THE PREFERRED EMBODIMENT

A preferred embodiment of the invention will be described with reference to the accompanying drawings for illustrating the present invention.

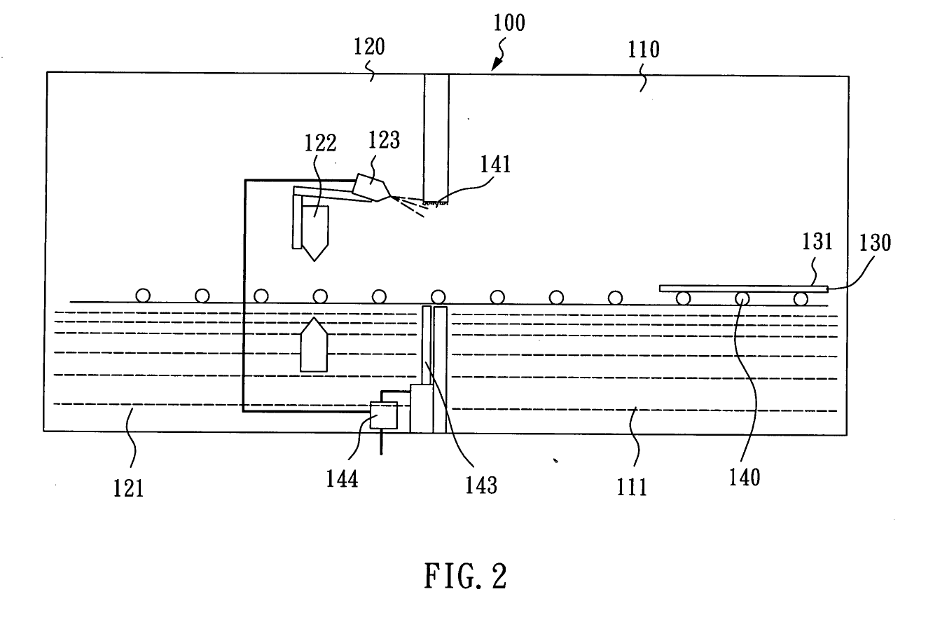

Referring to FIG. 2, a cross-sectional view of a stripper machine according to a preferred embodiment of the present invention is illustrated. The stripper machine 100 of this preferred embodiment is produced by Shibaura, having a reaction chamber to serve as a stripper chamber 100. A photoresist stripper 111, for example, TOK solvent manufactured by SanFu Inc., in the stripper chamber 100 has a temperature of about 65° C. to strip a photoresist layer 131 from the surface of a substrate 130. Room temperature deionized water 121 in a rinsing chamber 120 is used to purge the substrate 130 immediately after stripping the photoresist from the substrate 130 so that any residual photoresist stripper 111 still on the substrate is cleared away. The substrate 130 has been processed by a photoresist coating, an exposure and a development, perhaps together with an etching and/or an ion implementation prior to the removal of the residual photoresist. The process for stripping photoresist from the substrate surface is generally called a photoresist stripping. A pneumatic valve 143 is mounted between the stripper chamber 110 and the rinsing chamber 120, and is controlled to open or close by feeding a gas from a gas source 144. In a process within the stripper machine 100, the substrate 130 is delivered via a conveyor belt 140 to the stripper chamber 110 for stripping the photoresist. Then, the substrate 130 is delivered from the stripper chamber 110 to the rinsing chamber 120 for a purging process. After the purging, the substrate is delivered out of the rinsing chamber 120 to end the process. The timing of delivering the substrate 130 into the rinsing chamber 120 can be controlled by opening or closing the pneumatic valve 143.

There is residual photoresist stripper 111 on the substrate 130 when the substrate 130 enters the rinsing chamber 120. To avoid the residual photoresist stripper 111 from forming on the substrate 130 and to reduce the amount of the photoresist stripper 111 going into the rinsing chamber 120, a wind knife set 122 is mounted close to the pneumatic valve 143 in the rinsing chamber 120. Thus, the photoresist stripper 111 on the substrate 130 will be blown back to the stripper chamber 110 when the substrate 130 enters the rinsing chamber 120. Because the photoresist stripper 111 has a temperature higher than the deionized water 121, the stripper chamber 110 is at temperature higher than the rinsing chamber 120. As such, when the pneumatic valve 143 is opened, vapor of the photoresist stripper 111 or vapor of the deionized water 121 is condensed by cooling. Thus, condensed residues are generated in a position nearby the rinsing chamber 120, especially in a position 141 above the pneumatic valve 143. In this connection, a gas knife 123 having a gas outlet facing directly in a direction toward the position 141 above the pneumatic valve 143 is added to one side of the wind knife 122. The gas fed to the gas knife 123 is provided by the gas source 144. As shown in FIG. 2, the gas knife 123 is connected to the gas source 144 through a gas conduit. When the gas source 144 supplies a gas to the pneumatic valve 143 to close the pneumatic valve 143, the gas coming from the gas source 144 also enters the gas knife 123 via the gas conduit. The gas knife 123 blows off the condensed liquid which was generated in the position 141 above the pneumatic valve 143 until the pneumatic valve 143 is opened again. In the blowing-off by the gas knife 123, liquid droplets blown off by the gas knife 123 do not impinge on the substrate 130 because there is an interval of distance between the substrate 130 which just exited the pneumatic valve 143 and the substrate 130 which is on the way toward the pneumatic valve 143. When the substrate 130 passes a position below the pneumatic valve 143, the condensed liquid in the position 141 above the pneumatic valve 143 is removed or reduced. As a result, no condensed liquid droplets impinge on the substrate 130 whereby formation of water spots is eliminated.

In a modified embodiment of the present invention, the actuation of the blowing-off of the gas knife 123 is not particularly restricted only during the closed period of the pneumatic valve 143. With regulations of an angular orientation of the blowing-off of the gas knife 123 and the distance between the substrate 130 and the pneumatic valve 143 during the blowing-off of the gas knife 123, the gas knife 123 can start to blow during the open period of the pneumatic valve 143.

The ejected gas is directed specifically toward the position where condensed liquid is easily generated on the inner sidewalls of the doorway of the reaction chamber or the valve according to the present invention. Thus, the possibility of generating condensed liquid of a solvent on the inner sidewalls of the doorway of the reaction chamber or the valve is greatly reduced. Accordingly, the water-spotting contamination as a result of condensed liquid of the solvent on the substrate can be reduced. Furthermore, because the gas source of the gas knife can be supplied directly from the gas source of the pneumatic valve, the cost involved in adopting the method for removing process fluid or condensed liquid by adding the jet device to the inner or outer sidewalls of the reaction chamber according to the present invention is very low. The problem of water spots remaining on the substrate surface can be significantly improved. Thus, the production yield and component reliability are greatly increased.

Although the present invention has been explained in relation to its preferred embodiments, it is to be understood that many other possible modifications and variations can be made without departing from the spirit and scope of the invention as hereinafter claimed.

What is claimed is:

1. An apparatus for preventing a substrate from being contaminated by condensed liquid, comprising:
a reaction chamber having at least a doorway on one side for said substrate to enter or exit, wherein said chamber receives said substrate and a process fluid to proceed with a processing step;
a conveyor unit for delivering said substrate into or out of said reaction chamber via said doorway;
a first jet device disposed on the delivery route of said conveyor unit external to said reaction chamber to eject a gas in a direction toward said substrate on said conveyor unit; and
a second jet device disposed on one side of said doorway external to said reaction chamber to eject a gas in a direction toward said doorway.

2. The apparatus of claim 1, wherein said substrate is a glass substrate or a silicon wafer.

3. The apparatus of claim 1, wherein said conveyor unit is a roller or a conveyor belt.

4. The apparatus of claim 1, wherein said processing step is a photoresist stripping or an etching step.

5. The apparatus of claim 1, wherein said doorway is a pneumatic valve.

6. The apparatus of claim 1, wherein said process fluid is a photoresist stripper or an acid solution.

7. The apparatus of claim 1, wherein said first or second jet device is a nozzle, a gas knife or a wind knife.

8. A method for preventing a substrate from being contaminated by condensed liquid, comprising:
providing a reaction chamber having at least a doorway on one side for said substrate to enter or exit wherein said chamber receives said substrate and a process fluid to proceed with a processing step, a conveyor unit for delivering said substrate into or out of said reaction chamber via said doorway, a first jet device disposed on the delivery route of said conveyor unit external to said reaction chamber, and a second jet device disposed on one side of said doorway external to said reaction chamber; and
ejecting a gas out from said second jet device in a direction toward said doorway.

9. The method of claim 8, further comprising a step: ejecting a gas out from said first jet device in a direction toward said substrate on said conveyor unit on, before or after a gas is ejected from said second jet device in a direction toward said doorway.

10. The method of claim 8, wherein said substrate is a glass substrate or a silicon wafer.

11. The method of claim 8, wherein said doorway is a pneumatic valve.

12. The method of claim 8, wherein said conveyor unit is a roller or a conveyor belt.

13. The method of claim 8, wherein said processing step is a photoresist stripping or an etching step.

14. The method of claim 8, wherein said process fluid is a photoresist stripper or an acid solution.

15. The method of claim 8, wherein said first or second jet device is a nozzle, a gas knife or a wind knife.

16. The method of claim 8, wherein said doorway is opened when a gas is ejected from said second jet device in a direction toward said doorway.

17. The method of claim 8, wherein said doorway is closed when a gas is ejected from said second jet device in a direction toward said doorway.
